(19) United States
(12) Patent Application Publication
(10) Pub. No.: US 2021/0148965 A1
(43) Pub. Date: May 20, 2021

(54) Inspection Method for Pins and Vias of Differential Signal Lines

(71) Applicants: Inventec (Pudong) Technology Corp., Shanghai (CN); Inventec Corporation, Taipei (TW)

(72) Inventor: Chih-Yun Chang, Taipei (TW)

(21) Appl. No.: 16/706,854

(22) Filed: Dec. 9, 2019

(30) Foreign Application Priority Data
Nov. 19, 2019 (CN) 201911136330.2

(51) Int. Cl. G01R 31/28

(52) U.S. Cl. CPC G01R 31/2815; G01R 31/2813

(57) ABSTRACT

A method of inspecting a printed circuit board includes confirming whether all parts of the printed circuit board need to be inspected, if inspecting all parts of the printed circuit board, checking pins and vias belonging to each differential signal line on the printed circuit board, and outputting an inspecting result.

### BACKGROUND OF THE INVENTION

### 1. Field of the Invention

The present invention is related to an inspection method for printed circuit boards, particularly to an inspection method for pins and vias of differential signal lines on printed circuit boards.

### 2. Description of the Prior Art

Because the current layout density on printed circuit boards (PCBs) has greatly increased with many high-speed differential signal lines, it is easy for engineers to make errors during the layout process. For example, on the same pair of differential signal lines corresponding positions and sizes of vias might not have correct layout, or the spacing between the vias is too wide.

A pair of differential signal lines consist of two signal lines with equal amplitudes, opposite phases, and matched terminals. The receiving terminal of the pair of differential signal lines compares the difference between the two received voltages to determine whether the transmitting terminal is sending a 0 or a 1. Even if the pair of differential signal lines are affected by noise during transmission, the noise effect can be canceled at the receiving terminal. So theoretically it would not be affected by noises. However, when the impedances of the pair of differential signal lines do not match, for example, the size of or the spacing between the vias being too large, the signal lines would then be affected by noise from the power supply, nearby circuit coupling or external electromagnetic interference. This would affect the integrity of the transmitted signal.

For a pair of differential signal lines to change layers through vias, there is the need to cut out the copper area (including power and ground) of all other signal lines on the inner layer of this pair of differential signal lines, and generate layout restricted area for specific layers. However, currently there is no reliable inspection program for engineers to check the size and position of vias and pins. They must be checked manually, which not only wastes time and labor costs, but also cannot ensure error free results.

### SUMMARY OF THE INVENTION

An embodiment provides a method of inspecting a printed circuit board. The method includes confirming whether all parts of the printed circuit board need to be inspected, if inspecting all parts of the printed circuit board, checking pins and vias belonging to each differential signal line on the printed circuit board, and outputting an inspecting result.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of an application environment the programming inspection method for pins and vias of differential signal lines a printed circuit board according to an embodiment of the present invention.

FIG. 2 is a flowchart of the programming inspection method for pins and vias of differential signal lines on a printed circuit board according to an embodiment of the present invention.

### DETAILED DESCRIPTION

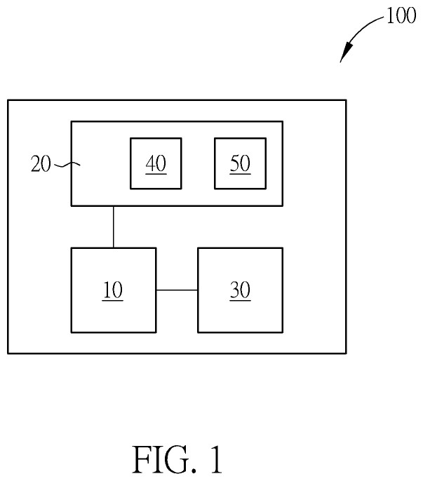

FIG. 1 is a diagram of an application environment the programming inspection method for pins and vias of differential signal lines a printed circuit board (PCB) according to an embodiment of the present invention. The programming inspection method for pins and vias of differential signal lines can be applied with a computer device 100. The computer device 100 may be an electronic device having a data processing capability, such as a personal computer, a laptop computer, or a server . . . etc. The computer device 100 includes a processor 10, a memory 20, and a display 30. The memory 20 can store one or more printed circuit board layout diagram files 40 and an automatic inspection program 50 for pins and vias of differential signal lines. The automatic inspection program 50 for pins and vias of differential signal lines is used to execute the programming inspection method 200 for pins and vias of differential signal lines.

The printed circuit board layout diagram file 40 contains all the layout information of a printed circuit board, including the path of the signal lines, the pin and the vias of the signal lines, and the signal lines binding data. The signal lines binding data identifies the same pair of differential signal lines. For example, if one signal line A0 is marked to bind to another signal line A1 in the printed circuit board layout diagram file 40, it means that the signal lines A0 and A1 are a pair of differential signal lines.

The memory 20 is for storing a printed circuit board layout diagram file 40 and the automatic inspection program 50 for pins and vias of differential signal lines. The memory 20 may be a storage device such as a hard disk, a flash memory, and a solid state drive. The processor 10 is for to executing the automatic inspection program 50 for pins and vias of differential signal lines. The display 30 is for displaying the content of the printed circuit board layout diagram file 40, and for displaying the user interface for the user to input inspection parameters and displaying inspection results.

The automatic inspection program 50 for pins and vias of differential signal lines can be applied to inspect all the pins and the vias of differential signal lines in the printed circuit board layout diagram file 40 to ensure that copper areas other than the differential signal lines are cut out and to generate layout restricted areas. This allows engineers to make layout modifications to prevent signal interference for the circuits.

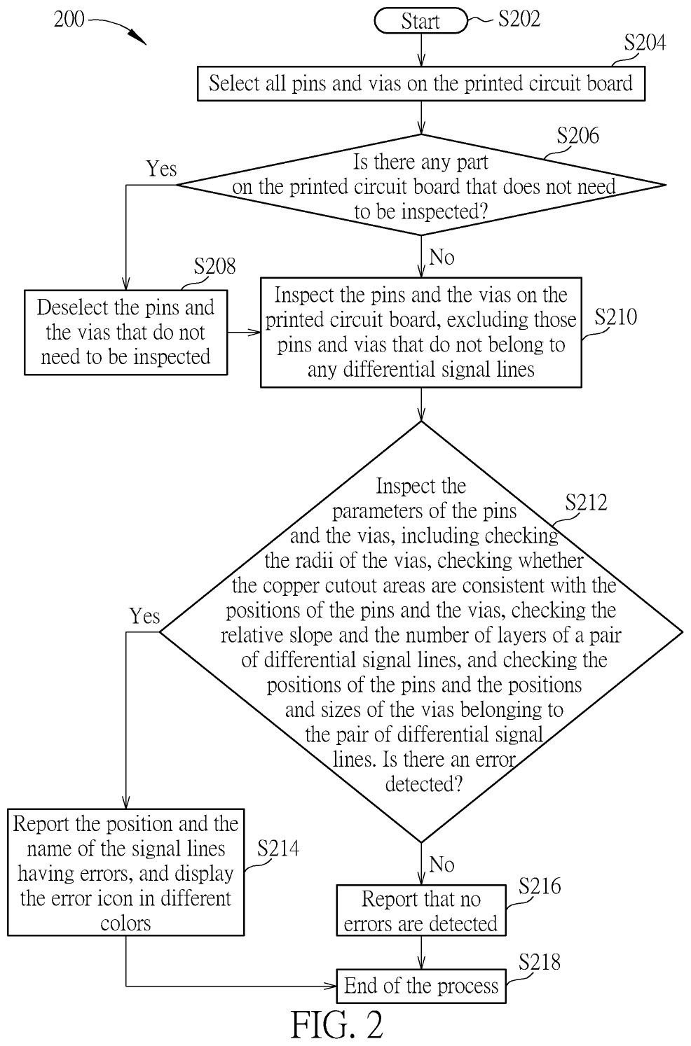

FIG. 2 is a flowchart of the programming inspection method 200 for pins and vias of differential signal lines on a printed circuit board according to an embodiment of the present invention. After the printed circuit board layout diagram file 40 is loaded into the automatic inspection program 50, the programming inspection method 200 can be applied to inspect the pins and the vias of differential signal lines in the printed circuit board layout diagram file 40. The method 200 includes the following steps:

S202: Start;

S204: Select all pins and vias on the printed circuit board;

S206: Is there any part on the printed circuit board that does not need to be inspected? If yes, proceed to step S208; if no, proceed to step S210;

S208: Deselect the pins and the vias that do not need to be inspected;

S210: Inspect the pins and the vias on the printed circuit board, excluding those pins and vias that do not belong to any differential signal lines;

S212: Inspect the parameters of the pins and the vias, including checking the radii of the vias, checking whether the copper cutout areas are consistent with the positions of the pins and the vias, checking the relative slope and the number of layers of a pair of differential signal lines, and checking the positions of the pins and the positions and sizes of the vias belonging to the pair of differential signal lines; if no errors are detected, proceed to step S216; if an error is detected, proceed to step S214;

S214: Report the position and the name of the signal lines having errors, and display the error icon indifferent colors; proceed to step S218;

S216: Report that no errors are detected;

S218: End of the process.

The programming inspection method 200 for pins and vias of differential signal lines requires parameters such as position of the pins and position, size and radii of the vias, and the routing layers of the differential signal lines. Without manual inspection by personnel, the programming inspection method 200 can determine whether the layout diagram violates any requirement according to the above parameters.

Step S210 can check the pins and the vias on the printed circuit board. If a pin or a via belongs to a power supply, ground, and other signal lines but not to a differential signal line, it will be excluded before proceeding further inspection.

In step S212, an error is reported if any of the following condition is detected: no layout restricted areas, the number of layers of the layout restricted areas not corresponding to the requirements, no copper cutout areas, the copper cutout areas being inconsistent with the position of the pins and the vias, and/or the copper cutout areas being inconsistent with the size of the vias.

In summary, the programming inspection method for pins and vias of differential signal lines on the printed circuit board according to the embodiment of the invention can provide a programming inspection method for engineers to check the pins and the vias of differential signal lines. Manual inspection can waste time and labor cost and also cannot ensure that the results satisfy the requirements. However, programming inspection for pin and vias is time efficient and low cost with higher inspection accuracy. It can quickly and accurately screen out differential signal lines with problems, thereby saving time and cost.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of inspecting a printed circuit board (PCB), comprising:
confirming whether all parts of the printed circuit board need to be inspected;
if inspecting all parts of the printed circuit board, checking pins and vias belonging to each differential signal line on the printed circuit board; and
outputting an inspecting result.

2. The method of inspecting a printed circuit board of claim 1, wherein checking the pins and the vias belonging to each differential signal line on the printed circuit board comprises:
checking radii of the vias belonging to each differential signal line on the printed circuit board.

3. The method of inspecting a printed circuit board of claim 1 further comprising:
checking whether positions of copper cutout areas on the printed circuit board correspond to positions of the pins and the vias.

4. The method of inspecting a printed circuit board of claim 1 further comprising:
checking number of layers and positions of layout restricted areas on the printed circuit board.

5. The method of inspecting a printed circuit board of claim 1, wherein checking the pins and the vias belonging to each differential signal line on the printed circuit board comprises:
checking a relative slope and number of layers of a pair of differential signal lines on the printed circuit board, positions of pins of the pair of differential signal lines, and positions and sizes of vias of the pair of differential signal lines.

6. A method of inspecting a printed circuit board, comprising:
confirming whether all parts of the printed circuit board need to inspected;
if inspecting only a part of the printed circuit board, checking pins and vias belonging to differential signal lines on the part of the printed circuit board; and
outputting an inspecting result.

7. The method inspecting a printed circuit board of claim 6, wherein checking the pins and the vias belonging to the differential signal lines on the part of the printed circuit board comprises:
checking radii of the vias belonging to the differential signal lines on the part of the printed circuit board.

8. The method inspecting a printed circuit board of claim 6 further comprising:
checking whether positions of copper cutout areas on the printed circuit board correspond to positions of the pins and the vias.

9. The method inspecting a printed circuit board of claim 6 further comprising:
checking number of layers and positions of layout restricted areas on the part of the printed circuit board.

10. The method inspecting a printed circuit board of claim 6, wherein checking the pins and the vias belonging to the differential signal lines on the part of the printed circuit board comprises:
checking a relative slope and number of layers of a pair of differential signal lines on the part of the printed circuit board, positions of pins of the pair of differential signal lines, and positions and sizes of vias of the pair of differential signal lines.
